(19) United States
(12) Patent Application Publication
(10) Pub. No.: US 2006/0124167 A1
(43) Pub. Date: Jun. 15, 2006

(54) Thermal-efficient power converter enclosure for solar panels

(76) Inventors: Xuejun Fan, Chandler, AZ (US); Jeff Lord, Schaumburg, IL (US); William Keith, Lake in the Hills, IL (US)

Correspondence Address: PHILIPS INTELLECTUAL PROPERTY & STANDARDS, P.O. BOX 3001, BRIARCLIFF MANOR, NY, 10510, US

(21) Appl. No.: 11/301,404

(22) Filed: Dec. 13, 2005

Related U.S. Application Data
(60) Provisional application No. 60/636,367, filed on Dec. 15, 2004.

(51) Int. Cl. H01L 25/00

(52) U.S. Cl. 136/251; 136/244

(57) ABSTRACT

A solar power system includes an enclosure (230) for a power converter (120) that can be mounted adjacent to the solar panel (110), wherein the enclosure (230) is configured to allow a substantial air space (240) between the solar panel (110) and the power converter (120). The surface (232) of the enclosure (230) that is exposed to the solar energy comprises highly solar-irradiation-resistant material, to minimize the solar heating of the power converter (120), and vents (231) are provided in the enclosure (230) to facilitate airflow through the air space (240). Preferably, a thermal efficient housing (250) is provided to contain the power converter (120), to facilitate the transfer of heat from the power converter (120) to the air space (240). The housing (250) may also be configured to be weather-tight, to protect the components of the power converter (120).

This invention relates to the field of power systems, and in particular to a solar cell module that includes a thermally efficient power converter.

Solar cell systems typically include a solar panel wherein light energy is converted to an electric potential, and a power converter that converts this electric potential to a desired form. The power converter may, for example, convert the DC potential from a solar cell to an AC or DC voltage at a given voltage level, and may include voltage and/or current regulation capabilities.

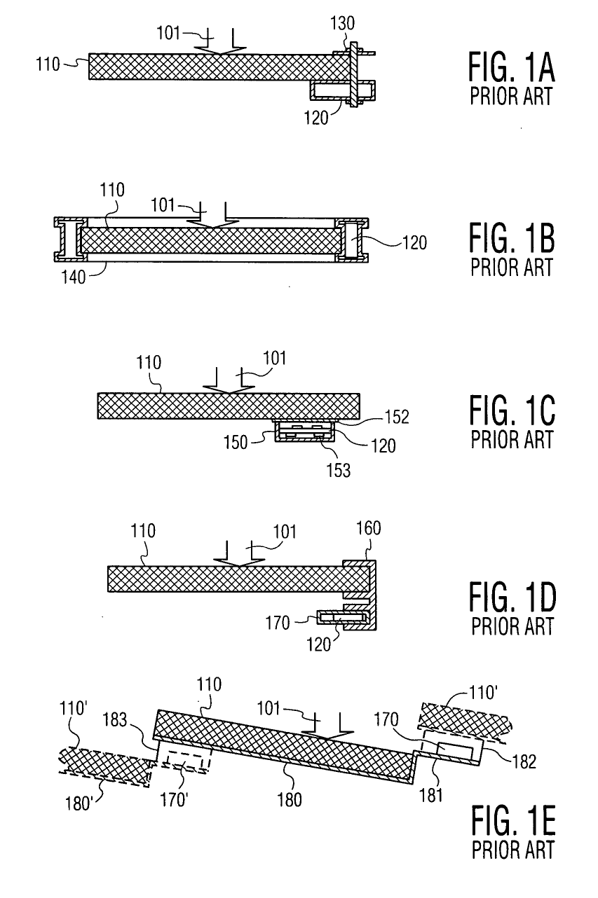

FIGS. 1A-1E illustrate examples of typical prior art configurations of solar panels 110 and power converters 120.

US patent publication 2003/0111103, “ALTERNATING CURRENT PHOTOVOLTAIC BUILDING BLOCK”, published 19 Jun. 2003 for Bower et al., and incorporated by reference herein, teaches a solar panel that uses a construct that is similar to the illustration in FIG. 1A, which includes a module mount 130 that is attachable to the solar panel 110, and is configured to position a power module 120 at the underside of the solar panel 10, opposite to the surface which is oriented to receive the incident light energy 101. In an alternative embodiment, this publication also teaches a solar panel that uses a construct that is similar to the illustration in FIG. 1B, wherein the power module 120 is located with a channel of a frame 140 that surrounds the solar panel 110.

Although some of the light energy 101 is converted to useful electrical energy by the solar panel 110, most of the light energy 101 is converted to heat energy, and in the example embodiment of FIG. 1A, the placement of the power module 120 upon the rear surface of the solar panel 110 subjects the power module 120 to a substantial amount of heat, which can shorten the life of the module 120 and adversely affect its performance and/or efficiency. In like manner, although placing the power module 120 within a channel of the frame 140 of FIG. 1B may result in less heat conduction than placing it upon a surface of the solar panel 110, a substantial amount of heat can be expected to be present within the channel. If the frame 140 is made of a heat conducting material, heat from the solar panel 110 will be conducted to the module 120. On the other hand, if the frame is made of a heat insulating material, the heat generated by the module 120 will be confined within the channel.

US published application 2002/0179140, “POWER CONVERTER AND PHOTVOLTAIC ELEMENT MODULE AND POWER GENERATOR USING THE SAME”, published 5 Dec. 2002 for Toyomura, and incorporated by reference herein, teaches a solar power system that uses a construct that is similar to the illustration in FIG. 1C, wherein the power module 120 is also attached directly to the underside of the solar panel 110, but in this embodiment, a weather-proof 150 housing that encloses the module 120 includes a first member 152 adjacent the solar panel that has low thermal conductivity, and a second member 153 that has a high thermal conductivity. The first member retards heat conduction from the solar panel 110 to the power module 120, and the second member facilitates heat conduction from the power module 120.

To further isolate the heat from the solar panel 110 from the power module 120, Japan patent publication JP 09-271179, “SOLAR BATTERY EQUIPMENT”, published 14 Oct. 1997 for Takeo et al., teaches a solar power system that uses a construct that is similar to the illustration in FIG. 1D, wherein a fixture 160 is used to provide an air space between a solar panel 110 and a housing 170 that includes the power module 120. The housing 170 is made of heat conducting material, to transfer heat from the power module 120 to the air space; in alternative embodiments, the housing 170 includes fins for improving the heat transfer.

Takeo also teaches an alternative embodiment, similar to the illustration in FIG. 1E, that is designed for roof mounting, wherein each solar panel 110, 110′ is mounted on a stepped frame 180, 180′ with its corresponding power module housing 170, 170′ mounted on the step 181. Each frame 180 also includes engagement pieces 182, 183 that serve to facilitate the attachment of the frames 180, 180′ to each other. These engagement pieces 182, 183 may include openings to facilitate air flow to the housing 170.

Although the embodiments of FIGS. 1C-1E reduce the heat transfer from the solar panels 110 to the power modules 120, and allow for heat transfer from the power modules 120, the power module 120 in these embodiments are each situated below a solar panel 110, and are typically subject to fairly high temperatures. Although the vertical distance between the solar panel 110 and the power module 120 can be increased to reduce this heat transfer, such an increase will disadvantageously increase the overall vertical size (depth) of each panel 110 and module 120 combination.

It is an object of this invention to provide a solar power system that effectively thermally isolates the solar panel from the power module. It is a further object of this invention to provide this thermal isolation without a substantial increase in the depth dimension of the solar power system.

These objects, and others, are achieved by a solar power system that includes an enclosure for a power module that can be mounted adjacent to the solar panel, wherein the enclosure is configured to allow a substantial air space between the solar panel and the power module. The surface of the enclosure that is exposed to the solar energy comprises highly solar-irradiation-resistant material, surface finish, or coating to minimize the solar heating of the power module, and vents are provided in the enclosure to facilitate airflow through the air space. Preferably, a thermal efficient housing is provided to contain the power module, to facilitate the transfer of heat from the power converter to the air space and to the enclosure. The housing may also be configured to be resistant to various forms of ingress, including dust, chemicals, mold, insects, and so on, and to be weather-tight, to protect the components of the power converter.

The invention is explained in further detail, and by way of example, with reference to the accompanying drawings wherein:

FIGS. 1A-1E illustrate example prior art solar panel and power module configurations.

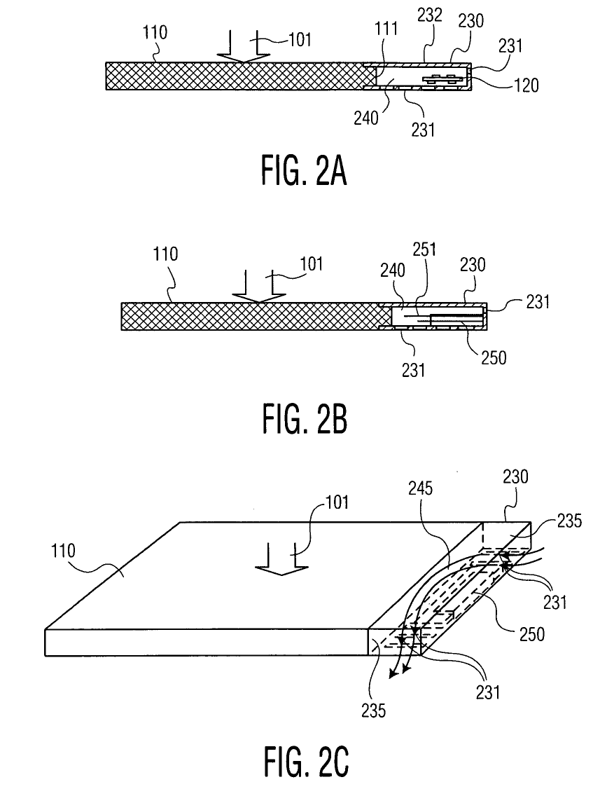

FIGS. 2A-2C illustrate an example solar panel and power module configuration in accordance with this invention.

Throughout the drawings, the same reference numeral refers to the same element, or an element that performs substantially the same function. The drawings are included for illustrative purposes and are not intended to limit the scope of the invention.

FIGS. 2A-2C illustrate an example solar panel 110 and power module 120 configuration in accordance with this invention.

As illustrated in FIG. 2A, the power module 120 is enclosed within an enclosure 230 that is configured to be mounted adjacent an edge 111 of the solar panel 110. At least the upper surface 232 of the enclosure 230, the surface that is primarily exposed to the solar energy 101, comprises a highly solar-irradiation-resistant material that is structured to minimize the amount of solar energy 101 that reaches the power module 120. Preferably, the enclosure 230 includes openings 231 that permit the flow of air through an air space 240 that separates the power module 120 from the solar panel 110. Alternatively, or additionally, the enclosure 230 could be open at each longitudinal end to facilitate the flow of air through the air space 240. The air flow may include either natural or forced convection, or both. In a preferred embodiment, the power module 120 is further enclosed within a housing 250, illustrated in FIGS. 2B and 2C. The housing 250 is preferably weather-tight, to protect the power module 120, and comprises one or more thermally conductive surfaces to facilitate the transfer of heat from the power module 120 to the air space 240. In a preferred embodiment, the housing 250 also includes fins 251 that serve as heat sinks to further facilitate the transfer of heat to the air space 240. The housing 250 is preferably structured so as to maintain an air space between the upper surface of the housing 250 and the upper surface of the enclosure 230, to avoid conduction of solar energy to the housing 250. Similarly, the housing 250 may also include insulation material that inhibits conduction of solar energy to the power module 120. In an alternative structure, the housing 250 may be mounted on the side wall of the enclosure 230, to further increase the separation of the power module 120 from the solar panel 110.

As illustrated in FIG. 2C, the openings 231 in the enclosure 230 facilitate an air flow 245 in the air space that separates the housing 250 from the solar panel 110 and from the upper surface of the enclosure 230. As noted above, the longitudinal ends 235 of the enclosure 230 may also be opened or otherwise vented to further facilitate the airflow 245. Although the airflow 245 is illustrated as flowing above the housing 250, alternative mounting techniques may be used to facilitate alternative airflows, including air flow above and below the housing 250. Similarly, and particularly in the case of a forced airflow, the airflow 245 may be part of a larger airflow system that facilitates the convention of heat from the enclosure 230 and the panel 110.

The openings 231 may be implemented in any of a variety of shapes, and may include features that facilitate the prevention of ingress of foreign objects. For example, the openings may include a mesh or screen to prevent the ingress of insects, and may include covering elements to prevent the ingress of rain, and so on. In like manner, the openings may be adjustable, including, for example, thermally activated elements that close the openings when airflow is not required, or voltage or current sensing elements that close the openings when power is not being provided by the panel 110.

As illustrated in FIGS. 2A-2C, the enclosure 230 is preferably configured to be the same depth as the solar panel 110. To achieve this depth, the power module 120 is constructed using techniques common in the art that minimize the height of the components placed on the circuit board that form the power module 120. For example, transistors with heat tabs may be mounted with the heat tabs parallel to the circuit board surface, with additional heat conductors provided to transfer the heat from the tab to the housing 250. Other techniques for minimizing the height of electronic devices are common in the art. Alternatively, to further facilitate airflow to the enclosure 230, the depth of the enclosure 230 may be configured to be greater than the depth of the solar panel 110.

The illustrated coupling of the enclosure 230 to the solar panel 110 in FIGS. 2A-2B, wherein the solar panel is shaped to allow the enclosure 230 to sandwich the panel 110 is presented for ease of illustration. Any of a variety of attachment techniques, common in the art, may be used to couple the enclosure 230 to the edge 111 of the solar panel 110. Preferably, the coupling of the enclosure 230 to the solar panel 110 is configured to minimize the amount of heat that is conducted from the solar panel to the enclosure 230, using, for example, a rail comprised of a low thermal conductivity material. The coupling of the enclosure 230 to the solar panel 110 may also be designed to facilitate the airflow 245 through the openings 231, including, for example, mounting the enclosure 230 at an angle relative to the plane of the solar panel 110. Optionally, the enclosure 230 may be coupled to the panel 110 via a hinge, so that the angle can be adjusted based on the particular installation of the system.

The foregoing merely illustrates the principles of the invention. It will thus be appreciated that those skilled in the art will be able to devise various arrangements which, although not explicitly described or shown herein, embody the principles of the invention and are thus within its spirit and scope. For example, although the enclosure 230 is illustrated as completely enclosing the housing 250, one of ordinary skill in the art will recognize that the lower surface of the enclosure 230 could include an opening that is configured to allow some or all of the lower surface of the housing 250 to be completely exposed, thereby facilitating the transfer of heat to the air outside the enclosure 230. These and other system configuration and optimization features will be evident to one of ordinary skill in the art in view of this disclosure, and are included within the scope of the following claims.

In interpreting these claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) each of the disclosed elements may be comprised of hardware portions (e.g., including discrete and integrated electronic circuitry), software portions (e.g., computer programming), and any combination thereof;

f) hardware portions may be comprised of one or both of analog and digital portions;

g) any of the disclosed devices or portions thereof may be combined together or separated into further portions unless specifically stated otherwise;

h) no specific sequence of acts is intended to be required unless specifically indicated; and

i) the term “plurality of” an element includes two or more of the claimed element, and does not imply any particular range of number of elements; that is, a plurality of elements can be as few as two elements.

1. A power system comprising:
a solar panel (110) comprising photoelectric elements that are configured to convert light energy to a first voltage,
a power converter (120) that is configured to convert the first voltage to an output voltage of the power system, and
an enclosure (230) that is configured to substantially enclose the power converter (120),
wherein
the enclosure (230):
is configured to be mounted adjacent to an edge (111) of the solar panel (110) so as to place the power converter (120) at a lateral distance from the solar panel (110) that provides a substantial air space (240) between the solar panel (110) and the power converter (120), and
comprises at least one solar-irradiation-resistant surface (232) that is configured to minimize an amount of solar energy that reaches the power converter (120).

2. The power system of claim 1, wherein
the enclosure (230) has an enclosure (230) depth dimension that is substantially equal to a depth of the edge (111) of the solar panel (110), so as to provide the power system with a substantially flat upper and lower profile.

3. The power system of claim 1, wherein
the enclosure (230) has an enclosure depth dimension that is greater than a depth of the edge (111) of the solar panel (110).

4. The power system of claim 1, wherein
the enclosure (230) includes one or more ventilation openings (231) that provide an air flow (245) to the air space (240) between the solar panel (110) and the power converter (120).

5. The power system of claim 4, wherein
the one or more ventilation openings (231) are configured to prevent an ingress of foreign objects to an interior of the enclosure (230).

6. The power system of claim 4, wherein
the one or more ventilation openings (231) are configured to be adjustable.

7. The power system of claim 1, further including
a housing (250) that is configured to enclose the power converter (120), and includes conductive material that facilitates dispersing heat to the air space (240).

8. The power system of claim 7, wherein
the housing (250) is substantially weather-resistant.

9. The power system of claim 7, wherein
the housing (250) includes fins (251) that extend from beyond a volume that encloses the power converter (120).

10. The power system of claim 7, wherein
the housing (250) has a housing depth that is substantially less than a depth of the enclosure (230).

11. The power system of claim 7, wherein,
the housing (250) is mounted on a lower surface of the enclosure (230), opposite to the surface (232) that is configured to minimize the amount of solar energy that reaches the power converter (120).

12. The power system of claim 7, wherein
the housing (250) is mounted on a side wall of the enclosure (230), opposite the edge (111) of the solar panel (110).

13. The power system of claim 7, wherein
the housing (250) also facilitates dissipation of heat from the power converter (120) to an exterior of the enclosure (230).

14. The power system of claim 7, wherein
the housing (250) is configured to prevent ingress of foreign objects.

15. The power system of claim 1, wherein
the enclosure (230) is coupled to the solar panel (110) via a coupling that minimizes thermal transfer between the enclosure (230) and the solar panel (110).

16. The power system of claim 15, wherein
the coupling includes a rail of low thermal conductivity material on the edge (111) of the panel.

17. The power system of claim 1, wherein
the enclosure (230) is configured to be coupled to the solar panel (110) at an angle relative to a plane of the solar panel (110).

18. An apparatus comprising:
a power converter (120), and
an enclosure (230) that is configured to enclose the power converter (120), and to facilitate attachment to an edge (111) of a solar panel (110),
wherein
the power converter (120) is mounted in the enclosure (230) so that when the enclosure (230) is attached to the edge (111) of the solar panel (110), a substantial air space (240) is provided between the power converter (120) and the edge (111) of the solar panel (110), in a direction perpendicular to the edge (111) of the solar panel (110), and
the enclosure (230) comprises at least one surface (232) comprising solar-irradiation-resistant material that is configured to minimize an amount of solar energy that reaches the power converter (120) when the power converter (120) is mounted in the enclosure (230).

19. The apparatus of claim 18, wherein
the enclosure (230) includes one or more ventilation openings (231) that provide an air flow (245) to the air space (240) when the enclosure (230) is attached to the solar panel (110).

20. The apparatus of claim 18, wherein
the enclosure (230) is configured to be attached to the solar panel (110) via a coupling that minimizes thermal transfer between the enclosure (230) and the solar panel (110).

21. The apparatus of claim 18, further including
a housing (250) that encloses the power converter (120) and includes conductive material that facilitates dispersing heat to the air space (240).

22. The apparatus of claim 18, wherein
the housing (250) is substantially weather-tight.
